(19) United States
(12) Patent Application Publication
(10) Pub. No.: US 2009/0090000 A1
(43) Pub. Date: Apr. 9, 2009

(54) In-mould molding touch module and method for manufacturing the same

(76) Inventors: Sheng-Pin SU, Jhongli City (TW); Min-Yi Lee, Sindian City (TW)

Correspondence Address: HDLS Patent & Trademark Services, P.O. BOX 220746, CHANTILLY, VA, 20153-0746, US

(21) Appl. No.: 11/963,793

(22) Filed: Dec. 22, 2007

(30) Foreign Application Priority Data
Oct. 9, 2007 (TW) 096137800

(51) Int. Cl. H03K 17/96; C23C 14/34; H05B 6/00

(52) U.S. Cl. 29/832; 200/600; 29/847; 264/434

(57) ABSTRACT

An in-mould molding touch module includes a transparent conducting substrate and a molding rind. The transparent conducting substrate has an inner surface and an outer surface. The inner surface has a capacitive electrode layer formed thereon. The capacitive electrode layer is a touch sense circuit made of ITO, and the outer surface is configured for touching the touch sense circuit. The molding rind is integrated to contain a periphery of the transparent conducting substrate by an in-mould injecting mode.

### 1. FIELD OF THE INVENTION

The present invention relates to in-mould molding touch modules and methods for manufacturing the same, and more specifically, to a module employing an in-mould injecting technology to contain a touch panel having a sensing circuit.

### 2. DESCRIPTION OF THE RELATED ART

In-mould Touch is a technology of combining the in-mould injecting technology and the technology of manufacturing touch panels.

The in-mould injecting technology is widely used in the industry for molding some plastic products. The in-mould injecting technology employs a mold having a cavity corresponding to an object, which would be molded. Melting plastic is injected in the cavity to mold the object. Furthermore, the in-mould technology in the industry includes an in mold label (IML) technology, which inserts an attaching object into the cavity, and then injects the melting plastic into the cavity to contain the attaching object for manufacturing a compound integrated object. A patent WO No. 00/39883 discloses an antenna and a method for manufacturing the same, which employ the in mold label technology. The patent discloses inserting a plate having a conducting ink antenna circuit printed thereon, into a cavity of a mold; and then injects a material for manufacturing a product, into the cavity to manufacture the product containing the embedded antenna circuit therein for protecting the antenna circuit and preventing the antenna circuit from fretting and renting. However, the technology are not be used to manufacture the touch panel in industry.

Touch panels, for example, advanced capacitive touch panels in the industry, may touch an outer surface of the panel by a finger to produce a current signal. The touch panels are used gradually in displays of some electronic products, which include a conducting layer of indium tin oxide (ITO) coated on a glass substrate, a reticular touch control sense circuit, and a plurality of designed capacitance areas formed in intercrossed lines. The finger served as an intermedium, touches any of the capacitance areas to increase the current of the capacitor and produce a current signal for distinguishing coordinate values. The current signal is then converted and outputted into a host for performing a touch command. Therefore, the capacitive touch panels are controlled by a touch sense mode, and produce the signals without pressures. Therefore, the capacitive touch panels have an excellent touch sensitive capability. Furthermore, the capacitive touch panels only need to coat the conducting layer on the glass substrate to form a touch control circuit, thus they are prone to be designed thin.

However, the capacitive touch panels need to be combined with a rind in process, for being the touch panel of the electronic products. The rind is configured for loading the touch panel. For example, a TW patent No. M274735 discloses a liquid crystal display panel structure, which is manufactured by an attaching mode. That is, the liquid crystal display panel structure is manufactured by attaching the touch panel and the liquid crystal display panel in a rind. Therefore, the process is complex, and costs time. A ladderlike thickness, joint surface and gap are formed therein because of attaching the touch panel and the liquid crystal display panel to be prone to congregate dust.

Furthermore, the patent WO No. 00/39883 discloses a method for containing the antenna by the IML technology, but fails to disclose applying the IML into the touch panel. There is no relative technology to disclose whether an integrated touch module having the ITO and the substrate having the ITO coated thereon, may be manufacturing by the in-mould injecting technology.

What is needed is an in-mould molding touch module, which can solve the above problems.

### BRIEF SUMMARY

An in-mould molding touch module in accordance with a preferred embodiment of the present invention, includes a transparent conducting substrate and a molding rind. The transparent conducting substrate has an inner surface and an outer surface. The inner surface has a capacitive electrode layer formed thereon. The capacitive electrode layer is a touch sense circuit made of ITO, and the outer surface is configured for touching the touch sense circuit. The molding rind is integrated to contain a periphery of the transparent conducting substrate by an in-mould injecting mode.

A method for manufacturing an in-mould molding touch module in accordance with another preferred embodiment of the present invention, includes:
(1) selecting a transparent substrate having an outer surface for being touched, and an inner surface;
(2) coating a transparent ITO layer on the inner surface of the substrate by a vacuum sputtering mode;
(3) exposuring, developing and etching the ITO layer to form a touch sense circuit on the substrate for being served as a touch electrode layer of the substrate; and
(4) inserting the substrate having the electrode layer coated thereon into a cavity of an injecting device, and injecting a molding material into the cavity to form a molding rind integrated to contain a periphery of the substrate having the electrode layer coated thereon.

The present in-mould molding touch module and the present method for manufacturing the same, employ the substrate, which is comprised of the glass thin film having an excellent transparent capability and a high heat-resistance capability bearing the temperature in the injecting mold and the vacuum sputtering process. Furthermore, the electrode layer made of the ITO has a high heat-resistance capability bearing the mold temperature of the injecting device. Thus the method for manufacturing the in-mould molding touch module may be preformed successfully. Furthermore, the method can simplify the manufacturing processes and decrease the time to solve the problems brought by the conventional art.

The molding rind essentially includes an outer surface. The outer surface of the molding rind and the outer surface of the substrate are prone to be arranged on a plane by the in-mould injecting technology. Thus the in-mould molding touch module has a thin thickness, and eliminates ladderlike thickness and gaps formed between joint surfaces. Therefore, the in-mould molding touch module can prevent dust from congregating, and be prone to be designed thin for solving the problems brought by the conventional art.

Furthermore, the rind may be a rind for containing a display unit of an electronic device. The display unit is amounted on an inner surface of the touch sense circuit, and displays images through the transparent electrode layer and the substrate.

Other objects, advantages and novel features of the invention will become more apparent from the following detailed description when taken in conjunction with the accompanying drawings, in which:

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic, exploded-view of an electronic device having an in-mould molding touch module of a preferred embodiment of the present invention;

FIG. 2 is a schematic, crossed-view of the in-mould molding touch module of FIG. 1 along A-A;

FIG. 3 is a schematic, exploded-view of a substrate, which has an ITO layer coated thereon;

FIG. 4 is a schematic, exploded-view of the substrate, which etches the ITO layer of FIG. 3 to form a touch sense circuit served as an electrode layer;

FIG. 5 is a schematic, crossed-view of an in-mould molding process, which inserts the substrate of FIG. 4 into a cavity of an injecting device;

FIG. 6 is a schematic, crossed-view of the in-mould molding process, which closes the cavity of FIG. 5 and injects a molding material into the cavity;

FIG. 7 is a schematic, crossed-view of the in-mould molding process, which opens the cavity of FIG. 6 to form a molding rind, and the rind is integrated to contain an periphery of the substrate having the electrode layer; and

FIG. 8 is a schematic, crossed-view of the present invention, which discloses the rind contains a display unit.

### DETAILED DESCRIPTION

Reference will now be made to the drawings to describe a preferred embodiment of the present in-mould molding touch module, in detail.

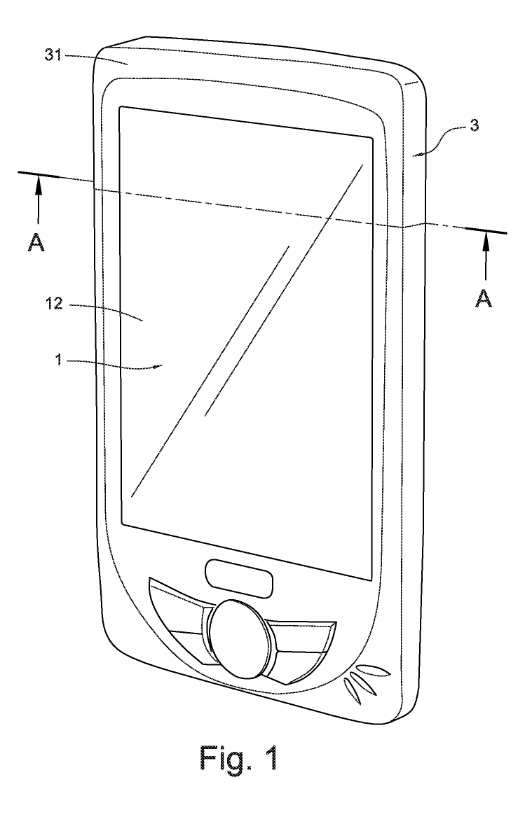

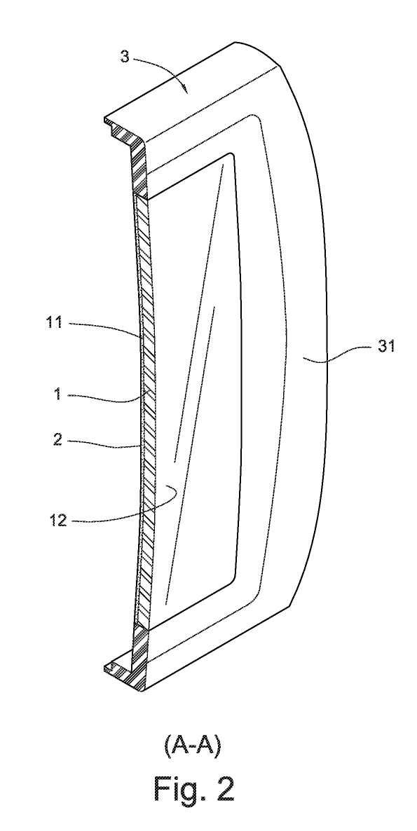

Referring to FIGS. 1 and 2, an in-mould molding touch module in accordance with a preferred embodiment of the present invention, is shown. The in-mould molding touch module includes a transparent conducting substrate 1 and a molding rind 3.

The transparent conducting substrate 1 includes an inner surface 11 and an outer surface 12 (referring to FIG. 8 together). The inner surface 11 has a capacitive electrode layer 2 formed thereon (referring to FIG. 4 together.) The capacitive electrode layer 2 is a touch sense circuit 21 made of the ITO. The outer surface 12 is configured for touching the touch sense circuit 21.

The molding rind 3 is integrated to contain the periphery 13 of the transparent conducting substrate 1 via the in-mould injecting mode.

Preferably, the transparent conducting substrate 1 is made of a transparent glass thin film, and the ITO is coated on the inner surface 11 of the transparent conducting substrate 1 via a vacuum sputtering mode. The molding rind 3 includes an outer surface 31 corresponding to a contour of a cavity. In-mould injecting, the outer surface 31 is prone to combine with the outer surface 12 of the transparent conducting plate 1 to be arranged in a plane. Thus the in-mould molding touch module has a thin thickness, and has no ladderlike thickness and gap arranged between the joint surfaces. Compared with the conventional art, the in-mould molding touch module prevents the dust congregated, and is prone to be thin.

Furthermore, in application, the present in-mould molding touch module is actually served as a touch panel for various displays. The rind 3 may be served as a rind for containing a display unit 6 (as shown in FIG. 8). The display unit 6 is amounted on an inner surface 210 of the touch sense circuit 21, and is displayed through the transparent electrode layer 2 and the transparent conducting substrate 1.

A method for manufacturing an in-mould molding touch module, in accordance with another preferred embodiment of the present invention, includes:

(1) selecting a transparent substrate 1. The transparent substrate 1 is essentially a transparent thin film made of glass, which can bear a temperature above 1000 centigrade degrees.

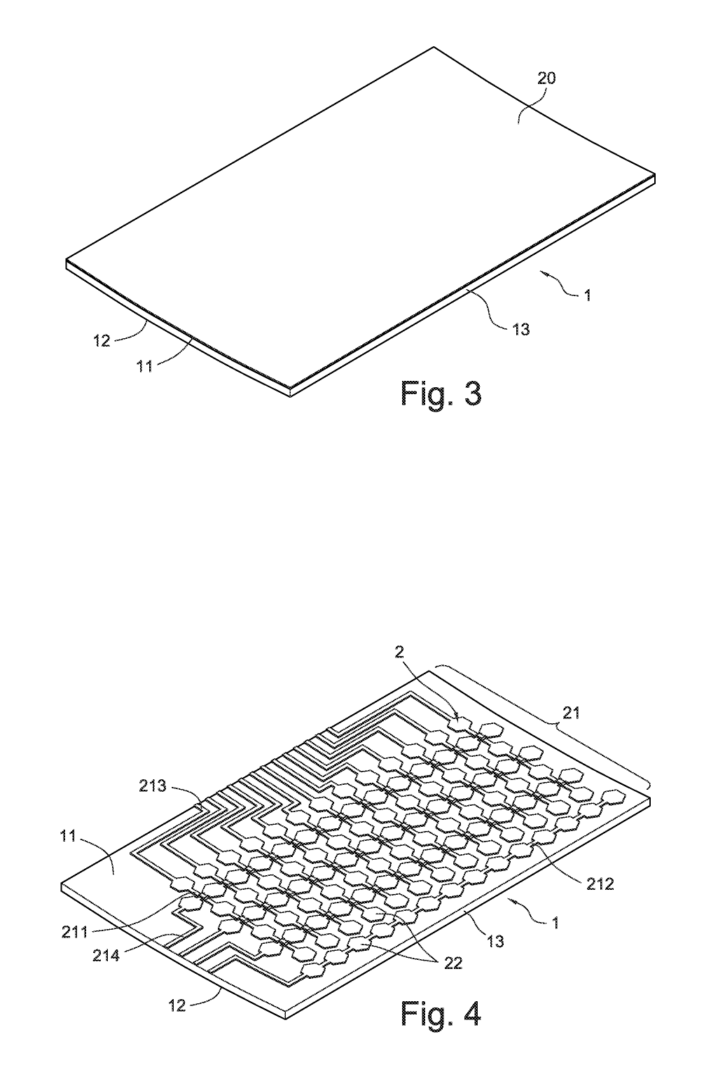

(2) coating a transparent ITO layer on an inner surface 11 of the transparent substrate 1 by a vacuum sputtering mode. Preferably, the transparent substrate 11 is arranged in a vacuum sputtering device. The vacuum sputtering device may be an advanced low-temperature vacuum sputtering nano-manufacturing device in the industry. An ITO target is bombarded by Ar ions to bombard atoms of the target and deposit on the inner surface 11 of the substrate 1 for form a transparent ITO layer 20 (as shown in FIG. 3) coated on the substrate 1. The transparent ITO layer 20 has an excellent conducting capability. Since the low-temperature vacuum sputtering technology has a working temperature below to 60 centigrade degrees, the glass substrate 1 may have a high steady capability in the vacuum sputtering process. Furthermore, in the working environment of the technology, the ITO layer may be deposited on a thermoplastic rubber, which cannot be used in the conventional art. The vacuum sputtering device may be used to perform a common PVD method. The ITO layer is excitated from the solid state to the gas state via the sputtering mode. Then the gas state atoms of the ITO, pass through the vacuum from the sputtering source to the inner surface 11 of the substrate 1, and are deposited to form the ITO layer at last. The PVD method performs the vacuum sputtering technology at a working temperature above 150 centigrade degrees. Therefore, a high heat-resistance glass is needed to be processed by the vacuum sputtering technology.

(3) exposuring, developing and etching the ITO layer 20 to form a reticular capacitive touch sense circuit 21 (as shown in FIG. 4) on the substrate 1 to be a touch electrode layer 2 of the substrate 1. A plurality of capacitive areas 22 are formed between the intercrossed lines 211, 212 of the touch sense circuit 21. The outer surface 12 of the touch substrate 1 is configured for the finger touching, and touching off the capacitive area 22 of the inner surface 11 of the touching location for sensing sensitively and increasing the current to produce a current signal corresponding to the coordinate values. The lines 211, 212 extend to electrically connect to at least two outer terminals 213, 214 configured for electrically connecting to a controller through a flexible circuit or a lead for outputting the current signal.

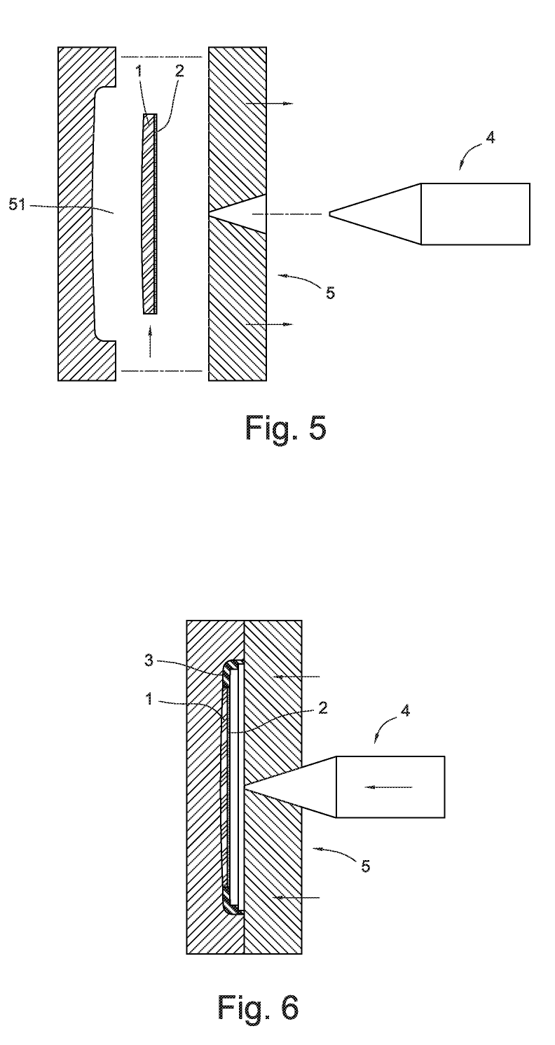

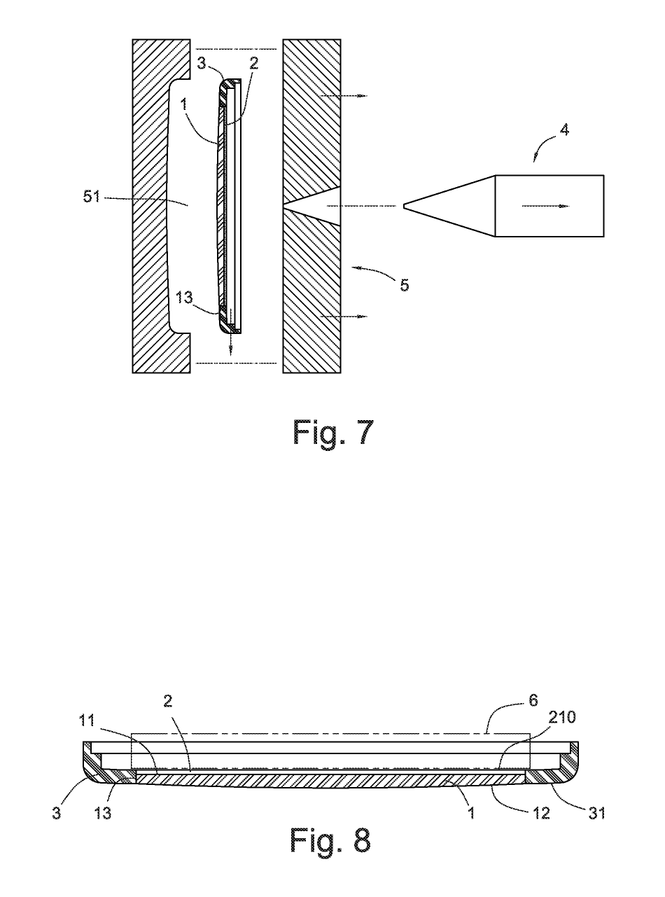

(4) inserting the substrate 1 having the electrode layer 2 coated thereon into a cavity 51 (as shown in FIG. 5) of an injecting device 4 to be served as an inserter of the cavity 51. The injecting device 4 may be a common device for injecting melting plastic, and include a mold 5 having the cavity formed therein. The cavity 51 is corresponding to the shape of the touch module. The cavity includes a space corresponding to the substrate 1, the electrode layer 2 and the molding rind 3 for containing the substrate 1 arranged therein. Furthermore, the processing temperature of the injecting melting plastic of the injecting device 4 is approximately 250 to 300 centigrade degrees, and the temperature of the cavity 51 is generally controlled between 60 to 150 centigrade degrees. Thus the substrate 1 made of glass, has an excellent steady capability. The mold 5 is closed, and the molding material (generally be melting rubber) is injected into the cavity 51 (as shown in FIG. 6). Then the mold 5 is open (as shown in FIG. 7) to form a molding rind (as shown in FIGS. 1, 2 and 8), which is integrated to contain the periphery 13 of the substrate 1 having the electrode layer 2 coated thereon.

From the above, the substrate 1 made of glass, is fit to be inserted into the cavity 51 to combine with the melting molding material after coating the electrode layer 2. Furthermore, the substrate 1 may be made of a material, which can fit the heating resistance condition of the manufacturing processes.

Since the method employs the molding rind 3 to contain the touch substrate 1 by the in-mould injecting technology, the method is easy to be performed in the injecting device having conditions of auto inputting material and outputting material. Therefore, the method can increase the auto producing capability. Compared with the conventional art, the method can simplify the manufacturing process, and decrease time cost.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. An in-mould molding touch module comprising:
a transparent conducting substrate having an inner surface and an outer surface, the inner surface having a capacitive electrode layer formed thereon, the capacitive electrode layer being a touch sense circuit made of ITO, and the outer surface being configured for touching the touch sense circuit; and
a molding rind integrated to contain a periphery of the transparent conducting substrate by an in-mould injecting mode.

2. The in-mould molding touch module as claimed in claim 1, wherein the substrate is comprised of a transparent glass thin film.

3. The in-mould molding touch module as claimed in claim 1, wherein the ITO is coated on the inner surface of the substrate by a vacuum sputtering mode.

4. The in-mould molding touch module as claimed in claim 1, wherein the rind has a display unit arranged therein.

5. The in-mould molding touch module as claimed in claim 1, wherein the rind touch sense circuit is made of ITO.

6. A method for manufacturing an in-mould molding touch module, comprising:
(1) selecting a transparent substrate having an outer surface for being touched, and an inner surface;
(2) coating a transparent ITO layer on the inner surface of the substrate by a vacuum sputtering mode;
(3) exposuring, developing and etching the ITO layer to form a touch sense circuit on the substrate for being served as a touch electrode layer of the substrate; and
(4) inserting the substrate having the electrode layer coated thereon into a cavity of an injecting device, and injecting a molding material into the cavity to form a molding rind integrated to contain a periphery of the substrate having the electrode layer coated thereon.

7. The method as claimed in claim 6, wherein the substrate is comprised of a transparent glass thin film.

8. The method as claimed in claim 6, wherein the rind includes a display unit configured for displaying images through transparent electrode layer and the substrate.
